(19) United States
(12) Patent Application Publication
(10) Pub. No.: US 2019/0263421 A1
(43) Pub. Date: Aug. 29, 2019

(54) DETERMINING DRIVING STATE VARIABLES

(71) Applicant: ZF Friedrichshafen AG, Friedrichshafen (DE)

(72) Inventor: Robert ZDYCH, Friedrichshafen (DE)

(21) Appl. No.: 16/321,266

(22) PCT Filed: Jul. 3, 2017
(86) PCT No.: PCT/EP2017/066466

§ 371 Date: Jan. 28, 2019

(30) Foreign Application Priority Data
Jul. 29, 2016 (DE) 10 2016 214 064.7

(51) Int. Cl. B60W 50/00; G07C 5/02; G07C 5/08; B60W 40/107; B60W 40/109; B60W 40/114; B60W 40/101; H03H 17/02

(52) U.S. Cl. CPC B60W 50/00; G07C 5/02; G07C 5/08; B60W 40/107; B60W 40/109; B60W 40/114; B60W 2050/0031; H03H 17/0257; B60W 2520/26; B60W 2520/105; B60W 2520/125; B60W 2050/0052; B60W 40/101

(57) ABSTRACT

A method (100) of determining driving state variables of a motor vehicle (105) includes scanning an input vector (u) of signals, which influence the driving state of the motor vehicle (105); scanning a first output vector (y) of variables, which describe the driving state of the motor vehicle (105); determining a second output vector (ŷ) of variables that describe the driving state of the motor vehicle (105) based on the input vector (u), a weighting vector (r) and a state vector (\hat{x}); and adapting the weighting vector based on the difference between the two output vectors (y, ŷ). In doing so, the observer includes a Kalman filter.

This application is a National Stage completion of PCT/EP2017/066466 filed Jul. 3, 2017, which claims priority from German patent application serial no. 10 2016 214 064.7 filed Jul. 29, 2016.

### FIELD OF THE INVENTION

The invention relates to determining driving state variables of a motor vehicle. In particular, the invention relates to modeling the motor vehicle to determine the driving state variables.

### BACKGROUND OF THE INVENTION

To understand and to assess the dynamics of a motor vehicle, or to enable the prediction or control of the motor vehicle, the state variables describing the movement of the motor vehicle have to be determined. For example, the ground speed of a motor vehicle can be determined using a speed sensor mounted at a wheel. The determination can be improved by using a plurality of speed sensors mounted at a plurality of wheels. However, this determination can be inaccurate, for instance if the slip exceeds predetermined critical value at several wheels. There are also state variables, which cannot be determined directly or not without significant additional effort, e.g. a float angle.

### SUMMARY OF THE INVENTION

The invention addresses the problem of specifying a technology that allows for an improved determination of driving state variables of a motor vehicle. The invention solves the problem by means of the subject matter of the independent claims. Dependent claims describe preferred embodiments.

It is proposed to use an observer based on a Kalman filter to achieve a very accurate mapping of an input vector of dynamic input values of the motor vehicle to an output vector. From the many different variants of Kalman filters available, one especially suitable variant is presented, which combines a good estimate of the state variable for this problem at an acceptable amount of time required for processing. In addition, a physical model of the motor vehicle is specified, on which the Kalman filter is based and that enables the accurate determination or prediction of state variables for this problem. The combination of preferred embodiments of the Kalman filter and the physical model of the motor vehicle can yield convincing results, on which control of the motor vehicle can be based. Typically, the motor vehicle comprises four wheels (front left, front right, rear left, and rear right), but other forms of motor vehicles can be supported, for example a single-track vehicle having two wheels or a two-track vehicle having more than two axles.

A method to determine driving state variables of a motor vehicle involves the steps of scanning a vector of input values that determine the driving state of the motor vehicle; scanning a first output vector of values, which describe the driving state of the motor vehicle; determining a second output vector of variables that describe the driving state of the motor vehicle based on the input vector, a state vector and a weighting vector; and the adjustment of the weighting vector based on the difference between the two output vectors. The observer described in that way is implemented using a Kalman filter.

The observer describes the behavior of the motor state vehicle by appropriately converting the input vector into an output vector using a physical model of the motor vehicle. The difference between the output vector determined relating to the observer and the output vector determined by the motor vehicle is fed back to the observer for weighting the mapping. Thus, the observer can map the behavior of the real motor vehicle by minimizing the difference between the output vectors.

The observer is based on a physical model of the motor vehicle, which is described further below. The physical model of the motor vehicle is preferably designed in a way that a multitude of driving state variables, which describe the dynamic behavior of the motor vehicle, can be determined without providing a specific sensor for every driving state variable. These driving state variables can be included in the state vector. A number of sensors to determine the driving state variables can be reduced. In addition, an error of measurement can be reduced. Every determined driving state variable can potentially be determined based on the measurement values of the input vector u and the output vector y, such that the accuracy of determination, the certainty of determination, or the speed of determination can be optimized. The observer can be used to better predict or estimate driving state variables that are difficult to determine using conventional methods, for instance a float angle.

Preferably the observer includes an “Unscented Kalman Filter” (UKF). The UKF enables an accurate determination of the desired driving state variables and requires acceptable processing capacities. In particular noisy measurements can only have little impact on the performance of the UKF. The UKF can be used to improve processing in real time, for example on board the motor vehicle. In particular preferably, the UKF includes a “Square Root Unscented Kalman Filter” (SR-UKF). The SR-UKF can be processed significantly faster than the UKF; under certain conditions, a 20% reduction of the required computation time compared to the UKF can be achieved. Different, non-linear observation algorithms can be used in other embodiments as well.

The proposed physical model of the motor vehicle is described in more detail below. In general, it is preferred that the input vector includes rotational speeds or, alternatively, angular speeds of the wheels of the motor vehicle and the wheel angles. The output vector preferably includes accelerations of the motor vehicle in longitudinal and transverse directions and a yaw rate. Based on the observer, driving state variables, which comprise at least a wheel force in longitudinal, vertical and transversal directions, can be determined; a wheel slip; a slip angle; a float angle, and a vehicle ground speed in longitudinal or transversal directions. Driving state variables relating to the wheel are preferably specified for every wheel of the motor vehicle.

It is preferred that the second output vector is determined based on a physical model, which can, for example, be expressed as equations of motion. In another preferred embodiment, adhesion coefficients between the tires of the motor vehicle and a roadway or an underground are determined and the physical model is modified on the basis of the specific coefficient of adhesions.

In this way, the relation between movement of a tire to the movement of the motor vehicle on the roadway can be determined.

If the observer includes a UKF, in particular a standard UKF, then the covariance matrix of measurements Rⁿ for a first variant can be modified as follows:

$${R}_{k}^{n} = \frac{1}{m} {\sum }_{j = 1}^{m} {v}_{k - j} \cdot {v}_{k - j}^{T} - {P}_{{\tilde{y}}_{k} , {\tilde{y}}_{k + 1}} {R}_{k + 1}^{n} ,$$

wherein vₖ₋ⱼ=yₖ₋ⱼ−y̅ₖ₋ⱼ⁻ is fixed and m≥IϵIN can be chosen arbitrarily. In a different variant, which can be used with an arbitrary non-linear Kalman filter as the observer, the covariance matrix Rⁿ of measurements is modified by means of a linear slave Kalman filter.

A computer program product comprises program code means for the implementation of the described method, if the computer program product runs on a processing device or is stored on a machine-readable data-storage medium.

A device for determining driving state variables of a motor vehicle implements a Kalman filter and is suited to implement the method described above. In particular, the device can comprise a programmable microcomputer. In that way, discrete-time processing can be executed in fixed time periods. The processing can be done in real time, i.e., specific processing times have a guaranteed maximum time.

The motor vehicle can be controlled based on the determined driving state variables. For example, an active chassis control, a break control, the control of a power train, or the control of an active or passive safety system on board the vehicle can be based on one or a plurality of the determined driving state variables.

### BRIEF DESCRIPTION OF THE DRAWINGS

The invention will now be described in more detail with reference to the attached figures, in which:

FIG. 1 describes a method; and

FIG. 2 describes a motor vehicle having different variables

### DETAILED DESCRIPTION OF THE PREFERRED EMBODIMENTS

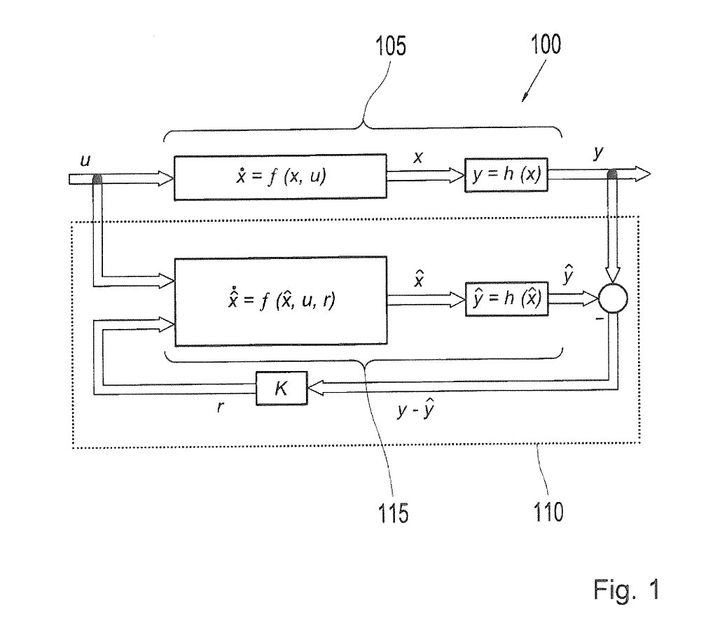

FIG. 1 shows a schematic representation of a method 100 for determining one or a plurality of driving state variables of a real motor vehicle 105 by means of an observer 110. The observer 110 can be regarded as a method and implemented by means of a programmable microcomputer, for instance. In that sense, the observer 100 can also be viewed as a device for determining driving state variables.

An input vector u includes measured values of the motor vehicle 105, for example wheel revolutions per minute nᵢ or, alternatively, angular speeds ωᵢ and wheel angles δᵢ of the individual wheels. These measurement values can be sampled using assigned sensors. For instance, an angular speed of a wheel ωᵢ can be measured using a magnetic or optical encoder.

The state of the motor vehicle 105 is described by a state vector x, which can include the vehicle speeds vₓ, v_{y} or a yaw rate \dot{ψ}. Typically, not all elements of the state vector x can be observed. A change \dot{x} in the state vector x is made based on a current state vector x and the input vector u. This influence can be seen as a function ƒ(x,u), which is generally not exactly known. Based on a function h(x), the influence results in an output vector y, which can comprise variables such as vehicle accelerations aₓ, a_{y} or the yaw rate \dot{ψ}. These variables variables can again be measured using appropriate sensors. For example, the acceleration can be measured using an inertia sensor and the yaw rate can be measured using a yaw rate sensor. These sensors can be designed micromechanically.

The mapping of the input vector u by the real motor vehicle 105 should be simulated as accurately as possible by means of an observer 110. In that way, an algorithm for determining driving state variables of the motor vehicle 105, which can be used to determine or predict driving state variables of the motor vehicle 105, is to be generated. Variables that relate to the observer 110 instead of the real motor vehicle 105 are denoted by a caret (e.g. â instead of a).

A physical model of the motor vehicle 115 implements a function ƒ(\hat{x}, u, r), which maps the state vector \hat{x} of the observer 110 to a change \hat{\dot{x}} of the state vector of the observer 110, based on the input vector u and a correction vector r. Based on a function h(\hat{x}), this change results in an output vector ŷ of the observer 110. The physical model of the motor vehicle 115 describes the driving characteristics of the motor vehicle 105 based in particular on physical interrelationships.

The difference between the output vector y and the output vector ŷ of the observer 110 is determined and transformed into the vector r by means of a so-called feedback matrix K. In this way, the error of the observer 110 is fed back to minimize it as much as possible.

The observer 110 has reached its steady state after a few passes through the feedback loop. Then, the output vector ŷ approximately equates to the output vector y of the real motor vehicle 105. Therefore, every element of the output vector ŷ can be determined quickly and accurately based on all elements elements of the input vector u and the output vector y. In that way, on the one hand, every element can be determined correctly, as potentially many measurement values have to be taken into account, on the other hand, even elements difficult to measure can be determined. For example, a float angle between the direction of movement of the motor vehicle 105 in the center of gravity CoG and the longitudinal axis of the vehicle can be determined without requiring an optical measuring system or a measuring wheel.

The determined elements typically include state variables of the motor vehicle and, for example, can be used to control the motor vehicle 105. For example, the determined speed of the motor vehicle can be used to control a brake system having anti-skid brakes (ABS), or a speed assistance system for controlling the speed at a predefined value, or be used by an electronic stability program (ESP). Other functionalities to control the movement or a convenience function of the motor vehicle 105 can also be based on the driving state variables determined by the observer 110. Of course driving state variables other than the speed can be utilized as well.

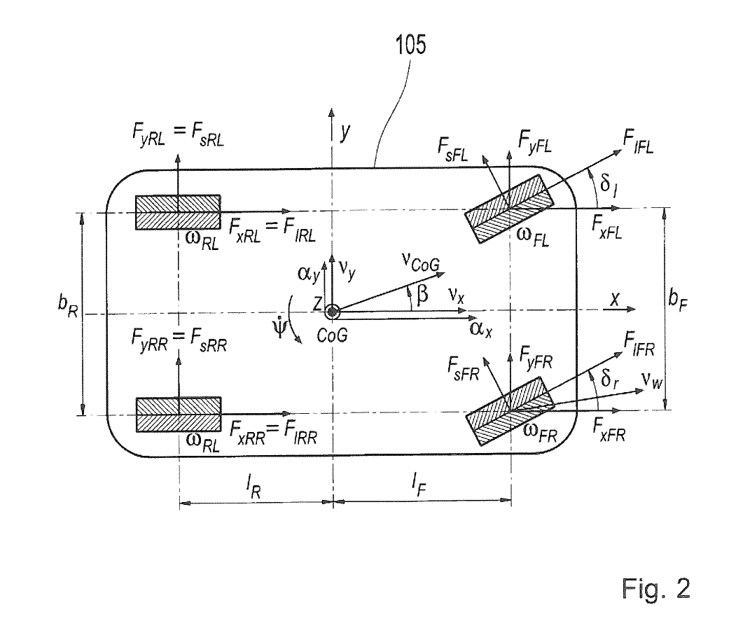

The method of the observer 110 is now mathematically described in greater detail. FIG. 2 shows related variables of the motor vehicle 105.

### Definitions

In general, the following notations apply:
R rear
F front
FL left front wheel
FR right front wheel
RL left rear wheel
RR right rear wheel
I in longitudinal direction (in the wheel coordinate system)
s in lateral or transversal direction (in the wheel coordinate system)
CoG center of gravity, origin of the motor vehicle/chassis coordinate system
m vehicle mass
Jz gyration moment of inertia
h_{COG} height of the center of gravity of the vehicle above ground
g gravitational acceleration
b_{F} track width of the motor vehicle at the front axle (front)
b_{R} track width of the motor vehicle at the rear axle (rear)
I_{F} distance of the front axle from the center of gravity along the longitudinal axis
I_{R} distance of the rear axle from the center of gravity along the longitudinal axis
v speed, in relation to the wheels
V speed, in relation to the center of gravity or the vehicle/chassis coordinate system
a acceleration
\dot{ψ} yaw speed=\dot{ψ}
R^{v} covariance matrix of the noise due to process noise
Rⁿ covariance matrix of the noise due to measuring noise
Bₗ; Dₗ; Caₗ; Eₗ; Bₛ; Dₛ; Caₛ; Eₛ: parameters of the tire model according to Pacejka
F force
x x direction (longitudinal axis in the vehicle/chassis coordinate system)
y y direction (longitudinal axis in the vehicle/chassis coordinate system)
z z direction (longitudinal axis in the vehicle/chassis coordinate system)
α slip angle: angle between the rotation level of a wheel and its direction of movement
α0 track correction (in the range of less than 1°)
β float angle
δ wheel angle
ω angular speed of the wheel
Sl slip in longitudinal direction
Ss slip in transversal direction
n number of revolutions of the wheel (alternative to the angular speed of the wheel)
vdiff difference in speed between the peripheral speed of the wheel and the resulting longitudinal speed of the wheel at the wheel contact patch
μ coefficient of adhesion
factor correction factor for the coefficient of adhesion
kfs correction factor for the lateral forces on the wheel

Speeds at the Wheel Contact Patch

vx_{FL}=Vx−\dot{ψ}·b_{F}/2

vx_{FR}=Vx−\dot{ψ}·b_{F}/2

vx_{RL}=Vx−\dot{ψ}·b_{R}/2

vx_{FR}=Vx−\dot{ψ}·b_{R}/2

vy_{FL}=Vy−\dot{ψ}·l_{F}

vy_{FR}=Vy−\dot{ψ}·l_{F}

vy_{RL}=Vy−\dot{ψ}·l_{R}

vy_{RR}=Vy−\dot{ψ}·l_{R}

Computation of the Slip Angle

α_{FL}=−δ_{FL}+arctan(vy_{FL}/vx_{FL})+α0_{FL}

α_{FR}=−δ_{FR}+arctan(vy_{FR}/vx_{FR})+α0_{FR}

α_{RL}=arctan(vy_{RL}/vx_{RL})+α0_{RL}

α_{RR}=arctan(vy_{RR}/vx_{RR})+α0_{RR}

Resulting Longitudinal Speeds of the Wheel at the Wheel Contact Patch

Vl_{FL}=\sqrt{(vx_{FL})²+(vy_{FL})²}·cos(α_{FL})

Vl_{FR}=\sqrt{(vx_{FR})²+(vy_{FR})²}·cos(α_{FR})

Vl_{RL}=\sqrt{(vx_{RL})²+(vy_{RL})²}·cos(α_{RL})

Vl_{RR}=\sqrt{(vx_{RR})²+(vy_{RR})²}·cos(α_{RR})

Switchover Between Drive Slip and Brake Slip

vdiff_{FL}=R_{FL}·ω_{FL}−vl_{FL}

if (vdiff_{FL}>0):

Sl_{FL}=1−vl_{FL}/(R_{FL}·ω_{FL});

or, if (vdiff_{FL}<0):

Sl_{FL}=(R_{FL}·ω_{FL})/vl_{FL}−1;

or, if (vdiff_{FL}=0):

Sl_{FL}=0.

vdiff_{FR}=R_{FR}·ω_{FR}−vl_{FR}

if (vdiff_{FR}>0):

Sl_{FR}=1−vl_{FR}/(R_{FR}·ω_{FR});

or, if (vdiff_{FL}<0):

Sl_{FR}=(R_{FR}·ω_{FR})/vl_{FR}−1;

or, if (vdiff_{FR}=0):

Sl_{FR}=0.

vdiff_{RL}=R_{RL}·ω_{RL}−vl_{RL}

if (vdiff_{RL}>0):

Sl_{RL}=1−vl_{RL}/(R_{RL}·ω_{RL});

or, if (vdiff_{RL}<0):

Sl_{RL}=(R_{RL}·ω_{RL})/vl_{RL}−1;

or, if (vdiff_{RL}=0):

Sl_{RL}=0.

vdiff_{RR}=R_{RR}·ω_{RR}−vl_{RR}

if (vdiff_{RR}>0):

Sl_{RR}=1−vl_{RR}/(R_{RR}·ω_{RR});

or, if (vdiff_{RR}<0):

Sl_{RL}=(R_{RR}·ω_{RR})/vl_{RR}−1;

or, if (vdiff_{RR}=0):

Sl_{RR}=0.

Ss_{FL}=α_{FL}

Ss_{FR}=α_{FR}

Ss_{RL}=α_{RL}

Ss_{RR}=α_{RR}

Resulting Slip

Sres_{FL}=\sqrt{(Sl_{FL})²·(Ss_{FL})²}

Sres_{FR}=\sqrt{(Sl_{FR})²·(Ss_{FR})²}

Sres_{RL}=\sqrt{(Sl_{RL})²·(Ss_{RL})²}

Sres_{RR}=\sqrt{(Sl_{RR})²·(Ss_{RR})²}

Coefficient of Adhesion Longitudinal According to the Tire Model by Pacejka

μl_{FL}=μ_{factor,l,FL}·Dl·sin(Caₗ·arctan(Bl·Sl_{FL}−El·(Bl·Sl_{FL}−arctan(Bl·Sl_{FL}))))

μl_{FR}=μ_{factor,l,FR}·Dl·sin(Caₗ·arctan(Bl·Sl_{FR}−El·(Bl·Sl_{FR}−arctan(Bl·Sl_{FR}))))

μl_{RL}=μ_{factor,l,RL}·Dl·sin(Caₗ·arctan(Bl·Sl_{RL}−El·(Bl·Sl_{RL}−arctan(Bl·Sl_{RL}))))

μl_{RR}=μ_{factor,l,RR}·Dl·sin(Caₗ·arctan(Bl·Sl_{RR}−El·(Bl·Sl_{RR}−arctan(Bl·Sl_{RR}))))

Adhesion Coefficient Transversal According to the Tire Model by Pacejka

μs_{FL}=μ_{factor,s,FL}·Ds·sin(Caₛ·arctan(Bs·Ss_{FL}·(Bs·Ss_{FL}−arctan(Bs·Ss_{FL}))))

μs_{FR}=μ_{factor,s,FR}·Ds·sin(Caₛ·arctan(Bs·Ss_{FR}·(Bs·Ss_{FR}−arctan(Bs·Ss_{FR}))))

μs_{RL}=μ_{factor,s,RL}·Ds·sin(Caₛ·arctan(Bs·Ss_{RL}·(Bs·Ss_{RL}−arctan(Bs·Ss_{RL}))))

μs_{RR}=μ_{factor,s,RR}·Ds·sin(Caₛ·arctan(Bs·Ss_{RR}·(Bs·Ss_{RR}−arctan(Bs·Ss_{RR}))))

Modification of the Adhesion Coefficients

In another preferred embodiment, the physical model of the motor vehicle described is adapted to the prevalent traction conditions based on the adhesion coefficients described above. It has to be observed that this adaptation can be used with any other non-linear observer algorithm.

The respective values are determined based on a measured acceleration a and an estimated acceleration â and then subtracted from each other. The resulting difference can be filtered before feeding it into a time-discrete integrator

$$( \frac{K \cdot Ts}{z - 1} ) .$$

The correction factors for every coefficient of adhesion μ_{factor_l_FL}, μ_{factor_l_FR}, μ_{factor_l_RL} and μ_{factor_l_RR}, if the respective longitudinal accelerations are used, as well as μ_{factor_s_FL}, μ_{factor_s_FR}, μ_{factor_s_RL} and μ_{factor_l_RR}, if the respective transversal accelerations are used, can be determined based on the output of the integrator. The previously determined coefficients of adhesion μₛ and μₗ can then be multiplied by a correction factor before further processing is performed.

$${μ}_{factor , i} = \frac{K \cdot Ts}{z - 1} ( \vert {a}_{x} \vert - \vert {\hat{a}}_{x} \vert )$$

$${μ}_{factor , s} = \frac{K \cdot Ts}{z - 1} ( \vert {a}_{y} \vert - \vert {\hat{a}}_{y} \vert )$$

Resulting Coefficients of Adhesion

μres_{FL}=\sqrt{(μl_{FL})²+(μs_{FL})²}

μres_{FR}=\sqrt{(μl_{FR})²+(μs_{FR})²}

μres_{RL}=\sqrt{(μl_{RL})²+(μs_{RL})²}

μres_{RR}=\sqrt{(μl_{RR})²+(μs_{RR})²}

Vertical Wheel Forces

$${F}_{F}^{norm} = m ( \frac{{l}_{R} g - {h}_{COG} {a}_{x}}{{l}_{F} + {l}_{R}} )$$

$${F}_{R}^{norm} = m ( \frac{{l}_{F} g + {h}_{COG} {a}_{x}}{{l}_{F} + {l}_{R}} )$$

$${Fz}_{FL} = ( \frac{1}{2} - \frac{{h}_{COG}}{{b}_{F}} \frac{{a}_{y}}{g} ) {F}_{F}^{norm}$$

$${Fz}_{FR} = ( \frac{1}{2} + \frac{{h}_{COG}}{{b}_{F}} \frac{{a}_{y}}{g} ) {F}_{F}^{norm}$$

$${Fz}_{RL} = ( \frac{1}{2} - \frac{{h}_{COG}}{{b}_{R}} \frac{{a}_{y}}{g} ) {F}_{R}^{norm}$$

$${Fz}_{RR} = ( \frac{1}{2} + \frac{{h}_{COG}}{{b}_{R}} \frac{{a}_{y}}{g} ) {F}_{R}^{norm}$$

Longitudinal Wheel Forces

Fl_{FL}=Sl_{FL}/Sres_{FL}·μres_{FL}·Fz_{FL}

Fl_{FR}=Sl_{FR}/Sres_{FR}·μres_{FR}·Fz_{FR}

Fl_{RL}=Sl_{RL}/Sres_{RL}·μres_{RL}·Fz_{RL}

Fl_{RR}=Sl_{RR}/Sres_{RR}·μres_{RR}·Fz_{RR}

Lateral Wheel Forces

Fs_{FL}=−kfs_{FL}·(Ss_{FL}/Sres_{FL}·μres_{FL}Fz_{FL})

Fs_{FR}=−kfs_{FR}·(Ss_{FR}/Sres_{FR}·μres_{FR}Fz_{FR})

Fs_{RL}=−kfs_{RL}·(Ss_{RL}/Sres_{RL}·μres_{RL}Fz_{RL})

Fs_{RR}=−kfs_{RR}·(Ss_{RR}/Sres_{RR}·μres_{RR}Fz_{RR})

Forced transformed into the vehicle/chassis coordinate system (specific to the center of gravity CoG)

Fx_CoG_{FL}=Fl_{FL}·cos(δ_{FL})−Fs_{FL}·sin(δ_{FL})

Fx_CoG_{FR}=Fl_{FR}·cos(δ_{FR})−Fs_{FR}·sin(δ_{FR})

Fx_CoG_{RL}=Fl_{RL}

Fx_CoG_{RR}=Fl_{RR}

Fy_CoG_{FL}=Fl_{FL}·sin(δ_{FL})−Fs_{FL}·cos(δ_{FL})

Fy_CoG_{FR}=Fl_{FR}·sin(δ_{FR})−Fs_{FR}·cos(δ_{FR})

Fy_CoG_{RL}=Fl_{RL}

Fy_CoG_{RR}=Fl_{RR}

Wind Resistance

Fw=C_AER_X·A_L·ρ_AER/2·(Vx)²

ax=1/m·(Fx_CoG_{FL}+Fx_CoG_{FR}+Fx_CoG_{RL}+Fx_Cog_{RR}−Fw)+\dot{Ψ}·Vy Equation of motion f1

ay=1/m·(Fy_CoG_{FL}+Fy_CoG_{FR}+Fy_CoG_{RL}+Fy_Cog_{RR})+\dot{Ψ}·Vx Equation of motion f2

\ddot{ψ}=1/Jz·(Fx_CoG_{FR}·b_{F}/2+Fy_CoG_{FR}·l_{F}−Fx_CoG_{FL}·b_{F}/2+Fy_CoG_{FL}·l_{F}+Fx_CoG_{RR}·b_{R}/2−Fy_CoG_{RR}·l_{R}−Fx_CoG_{RL}·b_{R}/2−Fy_CoG_{RL}·l_{R}) Equation of motion f3

The equations shown above characterize the preferred physical model that forms the basis of observer 110 in FIG. 1. It must be observed that the physical model of the motor vehicle described can be used with any arbitrary non-linear observer algorithm. Conversely, the observer described can work with any other physical model of the motor vehicle.

The observer 110 can be implemented using different non-linear Kalman filters, but a “Standard Unscented Kalman Filter” (UKF) is particularly preferred.

Modification of the Covariance Matrix of Measurements

Alternative 1:

When using a standard UKF, the covariance matrix Rⁿ can be modified as follows.

$${R}_{k}^{n} = \frac{1}{m} {\sum }_{j = 1}^{m} {v}_{k - j} \cdot {v}_{k - j}^{T} - {P}_{{\tilde{y}}_{k} , {\tilde{y}}_{k + 1}} {R}_{k + 1}^{n} ,$$

wherein vₖ₋ⱼ=yₖ₋ⱼ−ŷₖ₋ⱼ⁻ is fixed and m≥1ϵIN can be chosen arbitrarily as needed.

Also see “Covariance matching based adaptive unscented Kalman filter for direct filtering in INS/GNSS integration”, Yang Meng (*), Shesheng Gao (*), Yongmin Zhong (**), Gaoge Hu (*), Aleksandar Subic (***). Where: (*) School of Automatics, Northwestern Polytechnical University, Xi'an, China (**) School of Aerospace, Mechanical and Manufacturing Engineering, RMIT University, Australia (***) Swinbume Research and Development, Swinburne University of Technology, Hawthorn, Australia.

Alternative 2:

The covariance matrix of measurements Rⁿ of an arbitrary, non-linear Kalman filter can generally be modified by means of a linear slave Kalman filter as described in “Adaptive Unscented Kalman Filter and its Applications in Nonlinear Control”; Jianda Han, Qi Song and Yuqine He, State Key Laboratory of Robotics, Shenyang Institute of Automation, Chinese Academy of Sciences, P.R. China, chapter 4.

Kalman Filter

Below, preferred Kalman filters are described in more detail. The description was taken and adapted from “The Square-Root Unscented Kalman Filter for State and Parameter-Estimation”; Rudolph van der Merwe, Eric A. Wan; Oregon Graduate Institute of Science and Technology; 20000 NW Walker Road, Beaverton, Oreg. 97006, USA. A person skilled in the art should be familiar with the notations and terms used in the explanations below. Refer to the specified publication for more details.

In the past years, the Extended Kalman Filter (EKF) has become the preferred algorithm for many non-linear estimates and self-learning algorithms. The EKF applies the method of a linear standard Kalman filter to the linearization of a really non-linear system. This approach is often flawed and results in divergences. Therefore, it is preferred to use a UKF in the application at hand. In that way, a notably improved determination of driving state variables can be achieved. The computational complexity of a standard UKF using (O(L³)) is comparable to that of an EKF.

An estimation of the state of a time-discrete, non-linear, dynamic system is to be performed.

xₖ₊₁=F(xₖ,uₖ)+vₖ (eq. 1)

yₖ=H(xₖ)+nₖ, (eq. 2)

where xₖ refers to the observed state vector of the system, uₖ refers to a known input vector and yₖ refers to the observed output vector.

Initialization:

x₀= [symbol] [x₀]P₀= [symbol] [(x₀−\hat{x}₀)(x₀−\hat{x}₀)^{T}] (eq. 5)

for kϵ(1, . . . , ∞)

Determination of sigma points

χₖ₋₁=[\hat{x}ₖ₋₁\hat{x}ₖ₋₁+γ\sqrt{Pₖ₋₁}\hat{x}ₖ₋₁−γ\sqrt{Pₖ₋₁}] (eq. 6)

Update:

$$\begin{matrix}{χ}_{k \vert k - 1}^{*} = F [ {χ}_{k - 1} , {u}_{k - 1} ] & ( eq . 7 ) \\ {\hat{x}}_{k}^{-} = {\sum }_{i = 0}^{2 L} {W}_{i}^{( m )} {χ}_{i , k \vert k - 1}^{*} \\ {P}_{k}^{-} = {\sum }_{i = 0}^{2 L} {{W}_{i}^{( c )} [ {χ}_{i , k \vert k - 1}^{*} - {\hat{x}}_{k}^{-} ] [ {χ}_{i , k \vert k - 1}^{*} - {\hat{x}}_{k}^{-} ]}^{T} + {R}^{v} & ( eq . 8 ) \\ {}_{}^{5}{χ}{}_{k \vert k - 1}^{} = [ {\hat{x}}_{k}^{-} {\hat{x}}_{k}^{-} + γ \sqrt{{P}_{k}^{-}} {\hat{x}}_{k}^{-} - γ \sqrt{{P}_{k}^{-}} ] \\ {𝓎}_{k \vert k - 1} = H [ {χ}_{k \vert k - 1} ] & ( eq . 9 ) \\ {\hat{y}}_{k}^{-} = {\sum }_{i = 0}^{2 L} {W}_{i}^{( m )} {𝓎}_{i , k \vert k - 1} & ( eq . 10 )\end{matrix}$$

Equations to update the measurements:

$${P}_{{\hat{y}}_{k} , {\tilde{y}}_{k}} = {\sum }_{i = 0}^{2 L} {{W}_{i}^{( c )} [ {𝓎}_{i , k \vert k - 1} - {\hat{y}}_{k}^{-} ] [ {𝓎}_{i , k \vert k - 1} - {\hat{y}}_{k}^{-} ]}^{T} + {R}^{n}$$

$$\begin{matrix}{P}_{{x}_{k} {y}_{k}} = {\sum }_{i = 0}^{2 L} {{W}_{i}^{( c )} [ {χ}_{i , k \vert k - 1} - {\hat{x}}_{k}^{-} ] [ {𝓎}_{i , k \vert k - 1} - {\hat{y}}_{k}^{-} ]}^{T} & ( eq . 11 ) \\ {𝒦}_{k} = {P}_{{x}_{k} {y}_{k}} {P}_{{\tilde{y}}_{k} {\hat{y}}_{k}}^{- 1} & ( eq . 12 ) \\ {\hat{x}}_{k} = {\hat{x}}_{k}^{-} + {𝒦}_{k} ( {y}_{k} - {\hat{y}}_{k}^{-} ) & ( eq . 13 ) \\ {P}_{k} = {P}_{k}^{-} - {𝒦}_{k} {P}_{{\hat{y}}_{k} {\tilde{y}}_{k}} {𝒦}_{k}^{T} & ( eq . 14 )\end{matrix}$$

Where R^{v} represents the covariance matrix of the process noise and Rⁿ represents the covariance matrix of the measurement noise.

Preferably a “Square-Root UKF” is used as a refinement of the determination of the state. The following description of this variant of a Kalman filter is also taken from “The Square-Root Unscented Kalman Filter for State and Parameter-Estimation”.

\hat{x}₀= [symbol] [xₙ]S₀=chol{ [symbol] (x₀−\hat{x}₀)(x₀−\hat{x}₀)^{T}} (eq. 16)

for kϵ(1, . . . , ∞),

Determining and updating the Sigma point:

$$\begin{matrix}{χ}_{k - 1} = [ {\hat{x}}_{k - 1} {\tilde{x}}_{k - 1} + γ {S}_{k} {\hat{x}}_{k - 1} - γ {S}_{k} ] & ( eq . 17 ) \\ {χ}_{k \vert k - 1}^{*} = F [ {χ}_{k - 1} , {u}_{k - 1} ] & ( eq . 18 ) \\ {χ}_{k \vert k - 1}^{*} = {\sum }_{i = 0}^{2 L} {W}_{i}^{( m )} {χ}_{i , k \vert k - 1}^{*} & ( eq . 19 ) \\ {S}_{k}^{-} = qr \{ [ \sqrt{{W}_{1}^{( c )}} ( {χ}_{1 \text{:} 2 L , k \vert k - 1}^{*} - {\hat{x}}_{k}^{-} ) \sqrt{{R}^{v}} ] \} & ( eq . 20 ) \\ {S}_{k}^{-} = cholupdate \{ {S}_{k}^{-} , {χ}_{0 , k}^{*} - {\hat{x}}_{k}^{-} , {W}_{0}^{( c )} \} & ( eq . 21 ) \\ {}_{}^{5}{χ}{}_{k \vert k - 1}^{} = [ {\hat{x}}_{k}^{-} {\hat{x}}_{k}^{-} + γ {S}_{k}^{-} {\hat{x}}_{k}^{-} - γ {S}_{k}^{-} ] & ( eq . 22 ) \\ {𝓎}_{k \vert k - 1} = H [ {χ}_{k \vert k - 1} ] & ( eq . 23 ) \\ {\hat{y}}_{k}^{-} = {\sum }_{i = 0}^{2 L} {W}_{i}^{( m )} {𝓎}_{i , k \vert k - 1} & ( eq . 24 )\end{matrix}$$

Equations to update measurements:

$$\begin{matrix}{S}_{{\hat{y}}_{k}} = qr \{ [ \sqrt{{W}_{1}^{( c )}} [ {𝓎}_{1 \text{:} 2 L , k} - {\hat{y}}_{k} ] \sqrt{{R}_{k}^{n}} ] \} & ( eq . 25 ) \\ {S}_{{\hat{y}}_{k}} = cholupdate \{ {S}_{{\hat{y}}_{k}} , {𝓎}_{0 , k} - {\hat{y}}_{k} , {W}_{0}^{( c )} \} & ( eq . 26 ) \\ {P}_{{x}_{k} {y}_{k}} = {\sum }_{i = 0}^{2 L} {{W}_{i}^{( c )} [ {χ}_{i , k \vert k - 1} - {\hat{x}}_{k}^{-} ] [ {𝓎}_{i , k \vert k - 1} - {\hat{y}}_{k}^{-} ]}^{T} & ( eq . 27 ) \\ {𝒦}_{k} = ( {P}_{{x}_{k} {y}_{k}} / {S}_{{\hat{y}}_{k}}^{T} ) / {S}_{{\tilde{y}}_{k}} \\ {\tilde{x}}_{k} = {\hat{x}}_{k}^{-} + {𝒦}_{k} ( {y}_{k} - {\hat{y}}_{k}^{-} ) & ( eq . 28 ) \\ U = {𝒦}_{k} {S}_{{\tilde{y}}_{k}} & ( eq . 29 ) \\ {S}_{k} = cholupdate \{ {S}_{k}^{-} , U , - 1 \} & ( eq . 30 )\end{matrix}$$

Where R^{v} represents the covariance matrix of the process noise and Rⁿ represents the covariance matrix of the measurement noise.

### REFERENCE NUMERALS

100 Method
105 Motor vehicle
110 Observer
115 Physical model of the motor vehicle

1-11. (canceled)

12. A method (100) of determining driving state variables of a motor vehicle (105) using an observer (110), the method comprising:
scanning input vectors (u) of variables that determine the driving state of the motor vehicle (105);
scanning first output vectors (y) of the variables that describe the driving state of the motor vehicle (105);
determining, with the observer (110), second output vectors (ŷ) of the variables that describe the driving state of the motor vehicle, based on the input vectors (u), weighting vectors (r) and state vectors (\hat{x}); and
adapting (K), with the observer (110), the weighting vectors (r) based on a difference of the first and the second output vectors (y, ŷ); the observer (110) comprising a Kalman filter, which is formed as an Unscented Kalman Filter, and a covariance matrix of measurements (Rⁿ) being adapted by a linear slave Kalman filter.

13. The method (100) according to claim 12, wherein the observer (110) includes a Square Root Kalman Filter.

14. The method (100) according to claim 12, wherein the input vectors (u) comprise a number of revolutions (n) or angular speeds (ω) of wheels (FL, FR, RL, RR) of the motor vehicle (105) and a wheel angle (δ) of the wheels (FL, FR, RL, RR).

15. The method (100) according to claim 12, wherein the first and the second output vectors (y, ŷ) include accelerations (a) of the motor vehicle (105) in longitudinal and transversal directions as well as a yaw rate (\dot{Ψ}).

16. The method (100) according to claim 12, further comprising determining, on a basis of the observer (110), the driving state variables that include at least a wheel force (F) in a longitudinal, a vertical, or a transversal direction;
a wheel slip (S);
a slip angle (a);
a float angle (β); and
a vehicle ground speed (V) in either the longitudinal or the transversal direction.

17. The method (100) according to claim 12, further comprising determining the second output vector (ŷ) based on a physical model (f, h), and determining adhesive coefficients (μ) between tires of the motor vehicle (105) and a roadway on which the motor vehicle is traveling, and adapting the physical model (f, h) based on the coefficients of adhesion (μ).

18. The method (100) according to claim 12, wherein adapting a covariance matrix of measurement (Rⁿ) as follows:
$${R}_{k}^{n} = \frac{1}{m} {\sum }_{j = 1}^{m} {v}_{k - j} \cdot {v}_{k - j}^{T} - {P}_{{\tilde{y}}_{k} , {\tilde{y}}_{k + 1}} {R}_{k + 1}^{n} ,$$
wherein vₖ₋ⱼ=yₖ₋ⱼ−ŷₖ₋ⱼ⁻ is fixed and m≥lϵIN is arbitrarily chosen.

19. A computer program product using program code means to implement a method (100) of determining driving state variables of a motor vehicle (105) using an observer (110), the method including: scanning input vectors (u) of variables that determine the driving state of the motor vehicle (105); scanning first output vectors (y) of the variables that describe the driving state of the motor vehicle (105); determining, with the observer (110), second output vectors (ŷ) of the variables that describe the driving state of the motor vehicle, based on the input vectors (u), weighting vectors (r) and state vectors(\hat{x}); and adapting (K), with the observer (110), the weighting vectors (r) based on a difference of the first and the second output vectors (y, ŷ); the observer (110) comprising a Kalman filter, which is formed as an Unscented Kalman Filter, and a covariance matrix of measurements (Rn) being adapted by a linear slave Kalman filter; and the computer program product running on a processing device or is stored on a machine-readable data-storage medium.

20. A device (110) for determining of driving state variable of a motor vehicle (105), the device implements a Kalman filter and being set to execute a method (100) for determining the driving state variable of the motor vehicle including: scanning input vectors (u) of variables that determine the driving state of the motor vehicle (105); scanning first output vectors (y) of the variables that describe the driving state of the motor vehicle (105); determining, with the observer (110), second output vectors (ŷ) of the variables that describe the driving state of the motor vehicle, based on the input vectors (u), weighting vectors (r) and state vectors (\hat{x}); and adapting (K), with the observer (110), the weighting vectors (r) based on a difference of the first and the second output vectors (y, ŷ); the observer (110) comprising a Kalman filter, which is formed as an Unscented Kalman Filter, and a covariance matrix of measurements (Rn) is adapted by means of a linear slave Kalman filter.
